(19) United States
(12) Patent Application Publication
(10) Pub. No.: US 2024/0429184 A1
(43) Pub. Date: Dec. 26, 2024

(54) DIELECTRIC WAVEGUIDE FOR TRANSMITTING ELECTRICAL SIGNAL AND METHOD OF FORMING THE SAME

(71) Applicant: TAIWAN SEMICONDUCTOR MANUFACTURING COMPANY LTD., HSINCHU (TW)

(72) Inventors: YOU-CHENG LU, TAINAN CITY (TW); STEFAN RUSU, SUNNYVALE, CA (US)

(21) Appl. No.: 18/338,381

(22) Filed: Jun. 21, 2023

(51) Int. Cl. H01L 23/66; H01L 23/00; H01L 23/528; H01L 25/00; H01L 25/065

(52) U.S. Cl. CPC H01L 23/66; H01L 23/528; H01L 24/08; H01L 24/80; H01L 25/0652; H01L 25/50; H01L 2223/6627; H01L 2224/08145; H01L 2224/80895; H01L 2224/80896

(57) ABSTRACT

A semiconductor structure includes: a first electrical waveguide formed of a first dielectric material and configured to transmit an electrical signal; a second electrical waveguide formed of the first dielectric material and disposed adjacent to a first side of the first electrical waveguide; and a third electrical waveguide formed of the first dielectric material and disposed adjacent to a second side of the first electrical waveguide opposite the first side. The second electrical waveguide and the third electrical waveguide are configured to form a composite waveguide together with the first electrical waveguide for transmission of the electrical signal.

### BACKGROUND

Modern technology advances, such as big data, cloud computation, cloud storage, and Internet of Things (IoT), have driven exponential growth of various applications in processing and communications of data, e.g., high performance computers, data centers, and long-haul telecommunication. To address the emerging need of high data rate transmission, a modern semiconductor structure may include optical elements for providing optical data links to improve the data transmission rate of existing electrical data links. In the development of incorporating optical data links to the semiconductor device, the challenge of transmitting an electrical signal of an ultra-high bandwidth using a waveguide for reducing transmission loss has attracted a great deal of attention.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1A shows a block diagram of a cross-sectional view of a semiconductor package, in accordance with some embodiments of the present disclosure.

FIG. 1B shows block diagrams of a cross-sectional view and a top view of a vertical transition device, in accordance with some embodiments of the present disclosure.

FIG. 2A shows a block diagram of a cross-sectional view of a semiconductor package, in accordance with some embodiments of the present disclosure.

FIG. 2B shows a block diagram of an interposer die, in accordance with some embodiments of the present disclosure.

FIG. 3 shows a cross-sectional view of a dielectric waveguide, in accordance with some embodiments of the present disclosure.

FIGS. 4A, 4B, 4C and 4D are cross-sectional views of different dielectric waveguides, in accordance with some embodiments of the present disclosure.

FIGS. 5A, 5B and 5C are cross-sectional views of different dielectric waveguides, in accordance with some embodiments of the present disclosure.

FIGS. 6A, 6B, 6C and 6D are cross-sectional views of different dielectric waveguides, in accordance with some embodiments of the present disclosure.

FIGS. 7A and 7B show cross-sectional views of dielectric waveguides, in accordance with some embodiments of the present disclosure.

FIGS. 8A and 8B show cross-sectional views of dielectric waveguides, in accordance with some embodiments of the present disclosure.

FIGS. 9A and 9B show cross-sectional views of dielectric waveguides, in accordance with some embodiments of the present disclosure.

FIG. 10A shows a block diagram of a single-layer interconnect structure of optical devices, in accordance with some comparative embodiments of the present disclosure.

FIG. 10B shows a block diagram of a multilayer interconnect structure of optical devices, in accordance with some embodiments of the present disclosure.

FIG. 11 is a flowchart of a method of forming a semiconductor package, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “substantial” or “substantially” generally mean within 10%, 5%, 1% or 0.5% of a given value or range. Alternatively, the terms “about,” “substantial” or “substantially” mean within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “about,” “substantial” or “substantially.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

Embodiments of the present disclosure a interconnect structure including a dielectric waveguide for transmitting electrical signals, and a semiconductor die or a semiconductor package including the interconnect structure. Metallic or semiconductor-based conductive materials have been widely used as the transmission medium of power or electrical signals in a semiconductor device, e.g., a semiconductor die or a semiconductor package. Existing conductive lines or vias formed of the metallic materials or semiconductor materials can be fabricated with mature semiconductor fabrication processes with low cost and high fidelity. However, as the data transmission bandwidth is increased, the transmission loss also increases along with the data transmission frequency. For example, when the transmission frequency achieves the order of hundreds or gigahertz (GHz) or several terahertz (THz), the existing conductive transmission medium may cause a noticeable amount of transmission loss. The performance of the high-speed electronic circuits of the semiconductor structure may be compromised.

To address the aforementioned issues, the present disclosure proposes a dielectric waveguide for transmitting the electrical signal. An exemplary dielectric material for serving as the dielectric waveguide is silicon nitride, which can provide better transmission loss over silicon-based or metal-based materials in transmission of high-speed data. The electrical signal can be transmitted via the signal path formed of one or more dielectric waveguides formed of silicon nitride. The electrical signal propagating in the signal path may travel through the waveguides with a mode field diameter substantially equal to the composite cross-sectional areas of the waveguides. As a result, the electrical signal with a high-speed transmission rate can be transmitted in the semiconductor structure, semiconductor die or semiconductor package without conversion to or from optical signals. The signal processing and transmission would be more efficient and effective than existing optical transmission medium or the semiconductor/metallic transmission medium.

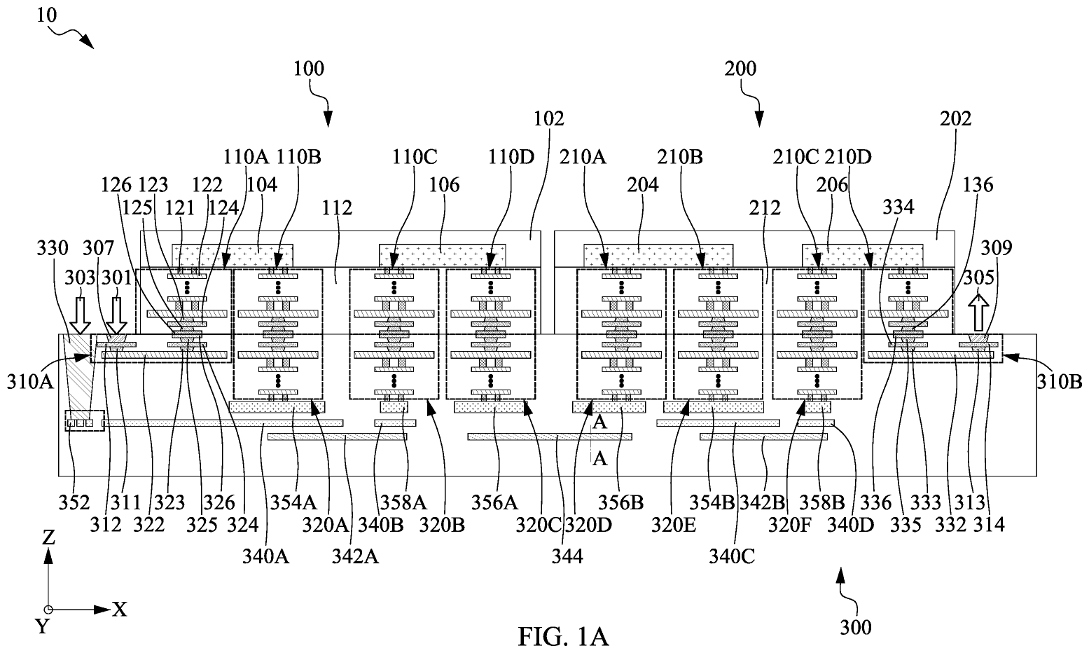

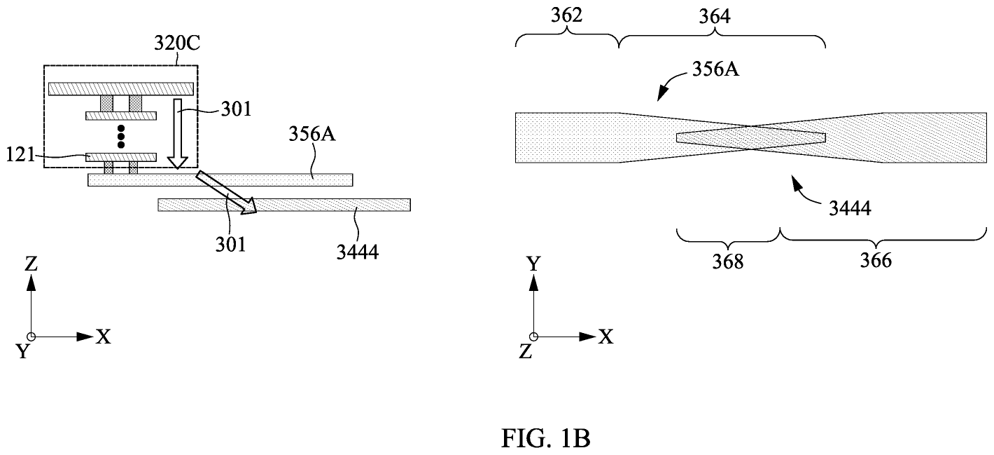

FIG. 1A shows a block diagram of a cross-sectional view of a semiconductor package 10, in accordance with some embodiments of the present disclosure. According to some embodiments, the semiconductor package 10 is a semiconductor device, a semiconductor die, a semiconductor structure, or the like. The semiconductor package 10 may include a first semiconductor die 100, a second semiconductor die 200 and a third semiconductor die 300. In other embodiments, the semiconductor package 10 may include less or more semiconductor dies, and other numbers of semiconductor dies are also within the contemplated scope of the present disclosure.

According to some embodiments, the first semiconductor die 100 or the second semiconductor die 200 is a logic die, a memory die, a processor die, a controller die, a field-programmable gate array (FPGA) die, a network interface die, a micro electromechanical system (MEMS) die, a transmitter die, a receiver die or the like. The first semiconductor die 100 or the second semiconductor die 200 includes input ports and output ports to receive or transmit high-speed electrical signals. The high-speed electrical signal is referred to herein as a signal in a certain band of the electromagnetic waves which has a frequency range greater than about 70 gigahertz (GHz) and below the band of optical signals, e.g., below about 100 terahertz (THz), below about 10 THz, below about 1 THz, below about 0.1 THz, or below about 300 GHz.

According to some embodiments, the first semiconductor die 100 includes a substrate 102 and an interconnect structure 112 over the substrate 102. The substrate 102 may include a substrate material, e.g., elementary silicon, elementary germanium or other suitable semiconductor materials. According to some embodiments, the substrate 102 includes doped regions doped with N-type dopants, e.g., arsenic, phosphorus, antimony, or the like, or doped with P-type dopants, e.g., boron, indium, or the like.

Electronic circuits 104 and 106 may be semiconductor devices formed on the substrate 102. The electronic circuits 104, 106 generally include one or more passive circuits, e.g., resistors, capacitors, inductors, diodes, fuses, or the like, and one or more active circuits, e.g., transistors. Each of the passive circuits or active circuits may be formed of one or more semiconductor layers, insulating layers, and conductive layers with respective patterned profiles or dimensions in compliance with the design requirements. According to some embodiments, the active circuits include bipolar junction transistors (BJTs) or metal-oxide semiconductor (MOS) field-effect transistor (FETs), in which the MOS FETs may include planar FETs, fin-type FETs (FinFFTs), gate-all-around (GAA) FETs, nanosheet FETs, nanowire FETs, or the like. According to some embodiments, the electronic circuit 104 is a transmitter configured to transmit electrical signals while the electronic circuit 106 is a receiver configured to receive electrical signals, or vice versa.

According to some embodiments, the interconnect structure 112 is configured to electrically connect the features in electronic circuits 104, 106 of the substrate 102. According to some other embodiments, the interconnect structure 112 is configured to electrically interconnect the electronic circuits 104, 106 to the circuits external to the first semiconductor die 100, e.g., the second semiconductor die 200 or the third semiconductor die 300. The interconnect structure 112 may include a plurality of conductive line layers and a plurality of conductive via layers, in which each of the conductive line layers includes a plurality of parallel conductive lines 122 extending in the horizontal direction, and each of the conductive via layers includes a plurality of parallel conductive vias 121 extending in the vertical direction. The conductive line 122 in a certain conductive line layer is electrically coupled to another conductive line 122 in an overlying conductive line layer or a underlying line layer through the conductive via 121 in an intervening conductive via layer.

According to some embodiments, the interconnect structure 112 includes a topmost conductive via layer including a plurality of conductive via 123 and a topmost conductive line layer including a plurality of conductive lines 124. The conductive line 124 is electrically connected to the underlying conductive lines 122 in the lower conductive line layers through the conductive via 123. According to some embodiments, the interconnect structure 112 further includes a bonding via layer including a plurality of bonding vias 125 and a bonding pad layer including a plurality of bonding pads 126. The bonding pad 126 is electrically connected to the conductive line 124 through the bonding via 125.

The conductive lines 122, 124, the bonding pad 126, the conductive vias 121, 123 and the bonding via 125 may be formed of conductive materials, such as doped polysilicon or metallic materials, e.g., copper, tungsten, aluminum, titanium, tantalum, silver, gold, titanium nitride, tantalum nitride, or other suitable metal-based materials. Each of the conductive lines 122, 124, the bonding pad 126 and the conductive vias 121. 123 and the bonding via 125 may be encapsulated by an electrically insulating material, such as silicon oxide or a polymeric material, such that each of the aforementioned conductive features in the interconnect structure 112 can be physically protected from an external force and electrically insulated from the adjacent conductive features to prevent undesired short circuit.

The interconnect structure 112 of the first semiconductor die 100 may include various signal paths 110 configured to transmit electrical signals between the substrate 102 and other devices external to the first semiconductor die 100. For example, the electronic circuit 104 is electrically coupled to the third semiconductor die 300 through a first signal path 110A and a second signal path 110B, in which each of the first signal path 110A and the second signal path 110B is formed of a plurality of conductive lines 122, 124, a plurality of conductive via 121, 123, at least one bonding via 125 and at least one bonding pad 126. Likewise, the electronic circuit 106 is electrically coupled to the third semiconductor die 300 through a third signal path 110C and a fourth signal path 110D, in which each of the third signal path 110C and the fourth signal path 110D is formed of a plurality of conductive lines 122, 124, a plurality of conductive via 121, 123, at least one bonding via 125 and at least one bonding pad 126. The signal paths 110A. 110B. 110C, and 110D are configured to transmit electrical signals, in which the electrical signals can be viewed as some specific types of electromagnetic waves in predetermined bands. According to some embodiments, the electrical signals transmitted in the first semiconductor die 100 are high-speed or high-bandwidth signals, and have a frequency in a range of less than about 100 THz, e.g., between about 70 gigahertz (GHz) and about 100 THz, or between about 70 GHz and about 10 THz.

According to some embodiments, the second semiconductor die 200 includes a substrate 202 and an interconnect structure 212 over the substrate 202. Electronic circuits 204 and 206 may be semiconductor devices formed on the substrate 202. The configurations, materials and functions of the substrate 202, the interconnect structure 212, and the electronic circuits 204, 206 of the second semiconductor die 200 are similar to their counterparts in the first semiconductor die 100, i.e., the substrate 102, the interconnect structure 112, and the electronic circuits 104, 106, and therefore these similar features will not be repeated for brevity.

According to some embodiments, the interconnect structure of the semiconductor die 200 includes a plurality of signal paths 210, e.g., a first signal path 210A, a second signal path 210B, a third signal path 210C, and a fourth signal path 210D. The electronic circuit 204 is electrically coupled to the third semiconductor die 300 through a first signal path 210A and a second signal path 210B, in which each of the first signal path 210A and the second signal path 210B is formed of a plurality of conductive lines 122, 124, a plurality of conductive via 121, 123, at least one bonding via 125 and at least one bonding pad 126. Likewise, the electronic circuit 206 is electrically coupled to the third semiconductor die 300 through a third signal path 210C and a fourth signal path 210D, in which each of the third signal path 210C and the fourth signal path 210D is formed of a plurality of conductive lines 122, 124, a plurality of conductive via 121, 123, at least one bonding via 125 and at least one bonding pad 126.

According to some embodiments, the third semiconductor die 300 is an interposer die, an interconnect die, an electronic die, an optical die, an electro-optical die, or the like. The third semiconductor die 300 is configured to provide one or more signal paths for transmitting high-speed data between the first semiconductor die 100 and the second semiconductor die 200.

According to some embodiments, the semiconductor package 10 includes a first signal source (not separately shown) and a second signal source (not separately shown) configured to provide a first input signal 301 and a second input signal 303 to the third semiconductor die 300. According to some embodiments, the third semiconductor die 300 is further configured to output an output signal 305. The first input signal 301 or the output signal 305 is an electromagnetic wave in the radio-frequency band or may be an electrical signal having a signal wavelength between about 0.3 mm (corresponding to one THz) and about 4.3 mm (corresponding to 70 GHz). The second input signal 303 is an electromagnetic wave in the optical signal band, which may be an optical signal having a signal wavelength between about 300 nm and about 2000 nm, e.g., at the 1310 nm and 1550 nm.

According to some embodiments, the third semiconductor die 300 further includes a first input port 307 and an output port 309 configured to receive the first input signal 301 and output the output signal 305, respectively. The first input port 307 and the output port 309 may be a conductive region formed of a conductive material, e.g., doped polysilicon or metallic materials such as copper, tungsten, aluminum, titanium, tantalum, alloys thereof, or the like. The second input port 308 may be an optical device configured to collect or focus the second input signal 303, and can be formed of a light pipe, an optical fiber, an optical waveguide, a lens assembly, or other suitable optical devices.

The third semiconductor die 300 includes an interconnect structure formed of a plurality of signal paths 310 and 320 encapsulated by the substrate 302. The substrate 302 may include a dielectric material, e.g., silicon oxide or a polymeric material. According to some embodiments, an input signal path 310A is configured to transmit the second input signal 303 to the first signal path 110A of the first semiconductor die 100 through the second input port 308, a conductive line 312, a conductive via 311, a conductive line 322, a conductive via 323, a conductive line 324, a bonding via 325 and a bonding pad 326. The first signal path 110A is electrically coupled to the input signal path 310A through bonding of the bonding pad 126 of the first signal path 110A and the bonding pad 326 of the input signal path 310A. According to some embodiments, the bonding pads 126 and 326 are bonded directly to each other without other solder materials or wiring. Further, according to some embodiments, an output signal path 310B is configured to transmit the output signal 305 from the fourth signal path 210D of the second semiconductor die 200 to the output port 309 through a bonding pad 336, a bonding via 335, a conductive line 334, a conductive via 333, a conductive line 332, a conductive via 313 and a conductive line 314. The fourth signal path 210D is electrically coupled to the output signal path 310B through bonding of the bonding pad 136 of the fourth signal path 210D and the bonding pad 336 of the output signal path 310B. According to some embodiments, the bonding pads 126 of the fourth signal path 210D and the bonding pad 326 are bonded directly to each other without other solder or wiring.

According to some embodiments, a plurality of transmission signal paths 320 are formed in the substrate 302. The configurations and materials of the transmission signal paths 320 are similar to the signal paths 110 and 210, and therefore the details of the transmission signal paths 320 will be omitted for the sake of brevity. A first transmission signal path 320A is provided to be electrically coupled to the second signal path 110B of the first semiconductor die 100 through the bonding of the bonding pad (not separately labelled) of the second signal path 110B and the bonding pad (not separately labelled) of the first transmission signal path 320A.

Likewise, a second transmission signal path 320B, a third transmission signal path 320C, a fourth transmission signal path 320D, a fifth transmission signal path 320E, and a sixth transmission signal path 320F are provided to be electrically coupled to the third signal path 110C, the fourth signal path 110D, the first signal path 210A, the second signal path 210B, and the third signal path 210C, respectively, of the first semiconductor die 100 or the second semiconductor die 200 through the bonding of the respective bonding pads (not separately labelled) of the signal paths 110, 210 and the corresponding bonding pads of the transmission signal paths 320.

According to some embodiments, the third semiconductor die 300 further includes a plurality of dielectric waveguides 340, 342, optical devices 352, 354, electronic devices 356, and electro-optical devices 358 configured to transmit or modulate the second input signal 303. According to some embodiments, the dielectric waveguides 340 or 342 are formed of elementary silicon or silicon nitride configured to transmit an electrical signal in the first input signal 301 and an optical signal in the second input signal 303. The critical dimensions of the dielectric waveguide 340, 342, e.g., the waveguide width, the waveguide thickness, and the like, are determined according to the transmission frequency (corresponding to a signal wavelength) of the input signal 301 or 303 travelling in the dielectric waveguide 340 or 342, and according to the reflective indices of the dielectric waveguides 340, 342.

In the depicted example, the dielectric waveguides 340, 342, e.g., the dielectric waveguide 340A, 342B, 340B, 340C, 342B and 340D are configured as optical waveguides to be part of a signal path for transmitting an optical signal of the second input signal 303. For example, the aforementioned optical dielectric waveguides 340, 342 are configured for transmitting a laser signal in a wavelength of about 1310 nm or about 1550 nm. In the depicted example, the dielectric waveguides 344 is configured as an electrical waveguide to be part of a signal path for transmitting an electrical signal of the first input signal 301. For example, the aforementioned electrical waveguide 344 is configured to transmit an electrical signal in a frequency of about 0.1 THz (corresponding to a wavelength of about 3.3 millimeter (mm)) or about one THz (corresponding to a wavelength of about 0.33 mm). The term “electrical waveguide” used throughout the present disclosure is meant to indicate that the waveguide is configured to transmit an electrical signal, rather than an optical signal or other bands of the electromagnetic signals. The electrical waveguide may be formed of a dielectric material, rather than an existing conductive element, to conduct the electrical signal at a certain wavelength or frequency, e.g., at a high frequency.

According to some embodiments, the optical device 352 is a grating coupler connected to the dielectric waveguide 340A and configured to guide the light beam of the second input signal to the dielectric waveguides 340A. The optical device 352 may include a plurality of periodic structures, referred to as gratings, to guide the light beam with a fiber mode and incident in the vertical direction to be coupled to the dielectric waveguides 340A in the horizontal direction and with a waveguide mode for achieving desired optical coupling efficiency.

According to some embodiments, the optical devices 354 are optical modulators configured to modulate the incoming light beam using the received electrical signal. For example, the optical modulators 354A is configured to modulate the light beams transmitted through the dielectric waveguide 340A from the grating coupler 352 using the electrical signal provided by the electronic circuit 104 through the second signal path 110B and the first transmission signal path 320A. The modulated light beam may change its phase according to the electrical field of the electrical signal provided by the electronic circuit 104. Similarly, the optical modulators 354B is configured to modulate the light beams transmitted through the dielectric waveguide 340C from the grating coupler 352 using the electrical signal provided by the electronic circuit 204 through the second signal path 210B and the fifth transmission signal path 320E. The modulated light beam may change its phase according to the electrical field of the electrical signal provided by the electronic circuit 204.

According to some embodiments, the electronic devices 356 are vertical transition devices serving as connectors and configured to couple the electrical signals from the first semiconductor die 100 to the dielectric waveguide 344 or from the dielectric waveguide 344 to the second semiconductor die 200. The electronic devices 356 may include dielectric materials, such as silicon nitride or semiconductor materials, such as elementary silicon, configured to transmit the electrical signals used in the first semiconductor die 100 or the second semiconductor die 200. Referring to FIG. 1B, a block diagram of a cross-sectional view and a top view of a vertical transition device 356A is shown, in accordance with some embodiments of the present disclosure. The vertical transition device 356A is arranged over a first end (e.g., the left-hand side end) of the dielectric waveguide 344. The vertical transition device 356A may include a transmission portion 362 and a tapered portion 364 connected to the transmission portion 362. The transmission portion 362 is electrically and physically coupled to the conductive vias 121 of the third transmission signal path 320C to receive the first input signal 301. The tapered portion 364 includes tapered sidewalls from a top-view perspective and tapers from the transmission portion 362 toward the dielectric waveguide 344. The widths and thicknesses of the transmission portion 362 and the tapered portion 364 are determined according to the transmission wavelength (equivalently the transmission frequency) of the first input signal 301. Similarly, the dielectric waveguide 344 may include a transmission portion 366 and a first tapered portion 368 connected to the transmission portion 366. The transmission portion 366 is electrically coupled to the vertical transition device 356B of the fourth transmission signal path 320D to transmit the first input signal 301 toward the second semiconductor die 200. The first tapered portion 368 includes tapered sidewalls from a top-view perspective and tapers from the transmission portion 366 toward the vertical transition device 356A. The widths and thicknesses of the transmission portion 366 and the first tapered portion 368 are determined according to the transmission wavelength (equivalently the transmission frequency) of the first input signal 301. The tapered portion 364 and the first tapered portion 368 are overlapped from a top-view perspective.

During operation, when the first input signal 301 travels from the conductive vias 121 of the third transmission signal path 320C and passes through the vertical transition device 356A, the electrical signal of the first input signal 301 is radiated out of the vertical transition device 356A along with the tapered sidewalls of the tapered portion 364. Meanwhile, the radiated electrical signal of the first input signal 301 is guided into the first tapered portion 368 of the dielectric waveguide 342B. The electrical signal of the first input signal 301 can therefore transmitted successfully through the vertical transition device 356A from the first semiconductor die 100 to the third semiconductor die 300.

The vertical transition device 356B may include a configuration and a material similar to those of the vertical transition device 356A. Although not separately illustrated, the vertical transition device 356B is arranged over a second end (e.g., the right-hand side end) of the dielectric waveguide 344. The vertical transition device 356B may also include a transmission portion and a tapered portion connected to the transmission portion. The dielectric waveguide 344 may also include a second tapered portion (not separately shown) on the second end of the dielectric waveguide 342B opposite the first tapered portion 368. During operation, the first input signal 301 travels through the transmission portion 366 of the dielectric waveguide 344 and reaches the second tapered portion at the second end of the dielectric waveguide 344. The electrical signal of the first input signal 301 is radiated out of the tapered portion of the dielectric waveguide 344 through the second tapered portion and guided into the tapered portion of the vertical transition device 356B. The electrical signal of the first input signal 301 can therefore transmitted successfully through the vertical transition device 356B from the third semiconductor die 300 to the second semiconductor die 200.

According to some embodiments, the electro-optical devices 358 are photodetectors or photodiodes configured to convert received photons into an electrical current as part of the first input signal 301. For example, the photodetector 358A is arranged at one end of the second transmission signal path 320B and configured to receive the optical signal transmitted from the dielectric waveguide 340B and convert an optical signal of the second input signal 303 to an electrical current as part of the first input signal 301. Likewise, the photodetector 358B is arranged at one end of the sixth transmission signal path 320F and configured to receive the optical signal transmitted from the dielectric waveguide 340D and convert the optical signal of the second input signal 303 to an electrical current as part of the first input signal 301.

According to some embodiments, the encapsulation material of the substrate 302 includes a dielectric material, e.g., silicon oxide or a polymeric material, different from the material of the dielectric waveguides 340, 342, 344. As discussion previously, the data bandwidth used in the first semiconductor die 100 or the second semiconductor die 200 is increased to the order of GHz or THz, and transmission loss of such a high-frequency signal between the first semiconductor die 100 and the second semiconductor die 200 would be greatly increased with the signal frequency using existing transmission medium, such as semiconductor materials or metallic materials. In contrast, the dielectric waveguide 344, which may adopt silicon nitride as the transmission medium, arranged in the third semiconductor die 300 is utilized as an electrical waveguide configured to transmit an electrical signal between the first semiconductor die 100 and the second semiconductor die 200. The transmission loss of the high-frequency electrical signal in the dielectric waveguide 344 is significantly lowered, and the conversion loss between the electrical transmission medium, e.g., a metal line, and the optical transmission medium, such as an optical waveguide, is saved since the electrical signal transmission can be maintained throughout the entire signal paths across the first semiconductor die 100, the second semiconductor die 200 and the third semiconductor die 300. The device complexity can therefore be greatly reduced, while signal transmission efficiency can be enhanced accordingly.

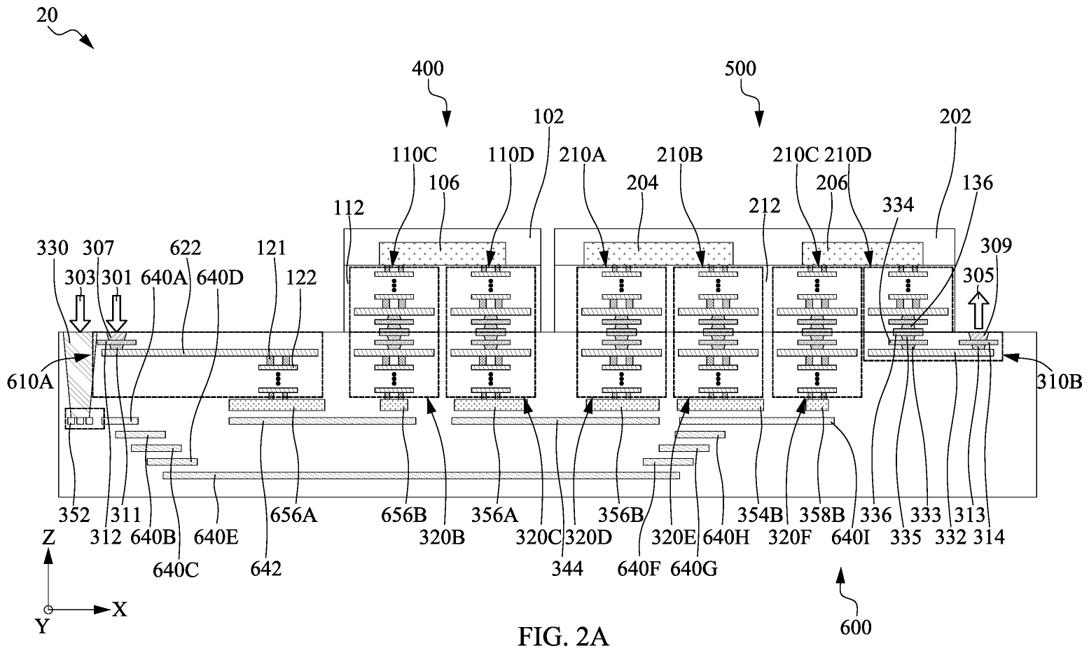

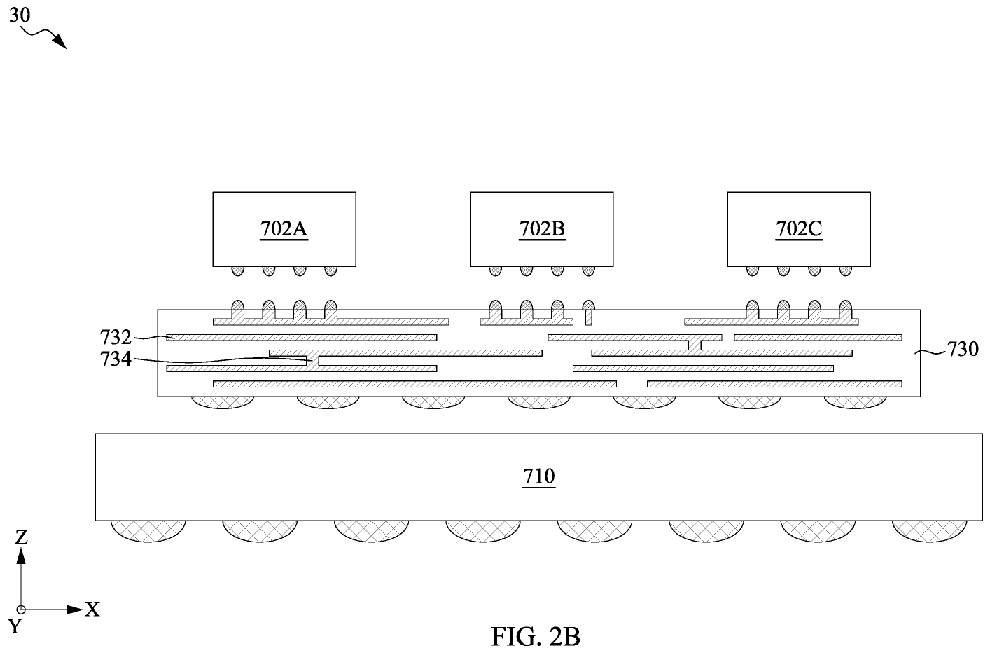

FIG. 2A shows a block diagram of a cross-sectional view of a semiconductor package 20, in accordance with some embodiments of the present disclosure. According to some embodiments, the semiconductor package 20 is a semiconductor device, a semiconductor die, a semiconductor structure, or the like. The semiconductor package 20 may include a first semiconductor die 400, a second semiconductor die 500 and a third semiconductor die 600. In other embodiments, the semiconductor package 20 may include less or more semiconductor dies, and other numbers of semiconductor dies are also within the contemplated scope of the present disclosure.

According to some embodiments, the first semiconductor die 400 or the second semiconductor die 500 is a logic die, a memory die, a processor die, a controller die, an FPGA die, a network interface die, a MEMS die, a transmitter die, a receiver die or the like. The first semiconductor die 400 or the second semiconductor die 500 includes input ports and output ports to receive or transmit high-speed electrical signals. According to some embodiments, the third semiconductor die 600 is an interposer die, an interconnect die, an electrical die, an optical die, an electro-optical die, or the like. The third semiconductor die 600 is configured to provide one or more signal paths for transmitting high-speed data between the first semiconductor die 400 and the second semiconductor die 500.

The first semiconductor die 400 may be similar to the first semiconductor die 100, while the second semiconductor die 500 may be similar to the second semiconductor die 500. Further, the third semiconductor die 600 may be similar to the third semiconductor die 300. The like numerals shown in FIGS. 1A and 2A represent like elements with similar functions, configurations and materials, and details of these similar features will not be repeated for the sake of brevity.

According to some embodiments, the electronic circuit 104 and the signal paths 110A and 110B shown in the first semiconductor die 100 are omitted from the first semiconductor die 400. Similarly, the first transmission signal path 320A shown in the third semiconductor die 300 are omitted from the third semiconductor die 600. Instead, the input signal path 310A shown in the third semiconductor die 300 are replaced with an input signal path 610A, in which the first input signal 301 is received by the first input port 307 and transmitted to the dielectric waveguide 354A through the conductive line 312, the conductive vias 311, a conductive line 622, the conductive lines 122 and the conductive vias 121.

According to some embodiments, the third semiconductor die 600 includes a plurality of dielectric waveguides 640 formed of elementary silicon or silicon nitride, and configured to be part of a signal path for transmitting an optical signal in the second input signal 303. For example, the dielectric waveguide 640A serves as an optical waveguide connected to the grating coupler 352 and configured to receive the optical signal in the second input signal 303. Further, the dielectric waveguide 6401 is optically coupled to the optical devices 354B and 358B and configured to transmit the optical signal of the second input signal 303 to the optical device 358B through the modulation of the optical device 354B. Moreover, the dielectric waveguides 640A, 640B, 640C, 640D. 640F, 640G and 640H are arranged in different layers of the third semiconductor die 600 and configured as vertical transition devices for transmitting the optical signal to different layers. The third semiconductor die 600 may further include a dielectric waveguide 640E overlapped with the first semiconductor die 400 and the second semiconductor die 500 from a top-view perspective and configured to transmit the optical signal between the vertical transition devices 640D and 640F. Although not separately illustrated, each of the dielectric waveguides 640 includes respective tapered portions configured to radiate the optical signal out of the respective dielectric waveguides or guide the optical signal into the respective dielectric waveguides.

According to some embodiments, the third semiconductor die 600 further includes electronic devices 656 serving as connectors formed of dielectric materials and configured to transmit the electrical signal in the first input signal 301. For example, the electrical devise 656A and 656B are configured to transmit and receive, respectively, the electrical signal travelling in the third semiconductor die 600.

According to some embodiments, the third semiconductor die further includes a dielectric waveguide 642 formed of silicon nitride and configured as part of a signal path for transmitting an electrical signal of the first input signal 301. For example, the dielectric waveguide 642A is electrically coupled to the electronic devices 656A and 658A and configured to transmit the electrical signal between the electronic devices 656A and 658A, in a manner similar to the dielectric waveguide 344.

According to some embodiments, the dielectric waveguides 340, 342, 344, 640, 642, which belong to different signal paths, are spaced apart from other by a suitable distance in order to prevent undesired electromagnetic wave coupling between different signal paths. For example, the dielectric waveguide 642 or 344 and the dielectric waveguide 640E are arranged in different layers of the third semiconductor die 600 and spaced apart from each other by a suitable vertical distance to prevent undesired electrical/optical coupling between the first input signal 301 and the second input signal 303.

FIG. 2B shows a block diagram of a semiconductor package 30, in accordance with some embodiments of the present disclosure. The semiconductor package 30 includes a first semiconductor device 710, a plurality of second semiconductor devices 720, e.g., second semiconductor devices 720A, 720B and 720C, and a third semiconductor device 730. The first semiconductor device 710 may be a substrate, e.g., a printed circuit board (PCB) with electronic circuits formed thereon. The second semiconductor devices 720A to 720C each may be one of a logic die, a memory die, a processor die, a controller die, an FPGA die, a network interface die, a MEMS die, a transmitter die, a receiver die or the like. According to some embodiments, the third semiconductor device 730 is an interposer die. The third semiconductor device 730 may be similar to the third semiconductor die 300 or 600 in many aspects, and these similar features will not be repeated for the sake of brevity. The third semiconductor device 730 may be used in electrically coupling the first semiconductor device 710 to the second semiconductor devices 720. According to some embodiments, the third semiconductor device 730 includes a plurality of layers, and each layer includes one or more dielectric waveguides 732 configured to transmit the electrical signals between the first semiconductor device 710 and the second semiconductor devices 720. According to some embodiments, the third semiconductor device 730 includes one or more conductive vias 734 formed of semiconductor material (e.g., doped polysilicon) or metallic materials (e.g., tungsten, aluminum, copper, gold, silver, titanium, tantalum, or the like), in which the conductive vias 734 extend vertically and are configured to be electrically and physically connected to the overlying or underlying dielectric waveguides 732 for transmitting the electrical signals. According to some other embodiments, the dielectric waveguides 732 include vertical transition devices formed of tapered portions configured to radiate the electrical signals to their corresponding tapered portions of adjacent dielectric waveguides 732 without involvement of the semiconductor-based or metal-based conductive vias 734, wherein the corresponding tapered portions of the adjacent dielectric waveguides 732 are configured to guide the radiated electrical signals into the transmission portions for achieving vertical transmission of the electrical signal.

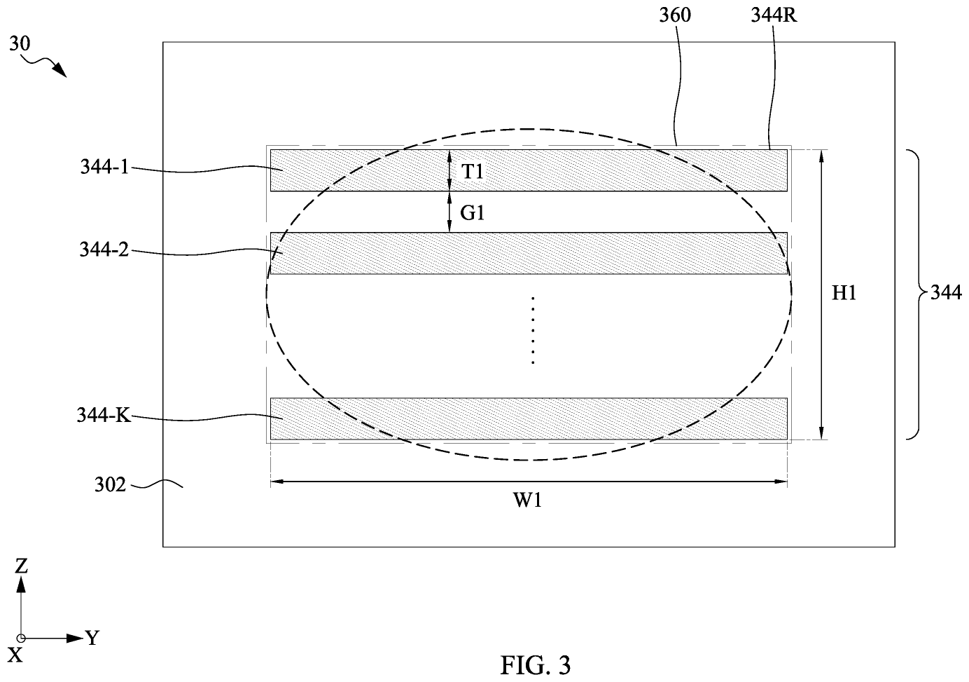

FIG. 3 shows a cross-sectional view of the dielectric waveguide 344, in accordance with some embodiments of the present disclosure. The cross-sectional view of FIG. 3 is taken along a sectional line AA of FIG. 1A. The dielectric waveguide 344 is a composite dielectric waveguide 344 formed of multiple waveguide plates, i.e., including one or more individual (or separate) dielectric waveguides plates 344-1, 344-2 and 344-K, wherein the index K denotes the number of the waveguide plates. Although the depicted example shows three waveguide plates 344-1 to 344-3 for the composite dielectric waveguide 344, the present disclosure is not limited thereto. The composite dielectric waveguide 344 can be formed of a plurality of waveguide plates 344-K with K being an integer greater than three.

According to some embodiments, a cross-sectional area of the composite dielectric waveguide 344 represented by a dotted box 344R has a waveguide width W1 and a waveguide height H1 measured in the cross section of the composite dielectric waveguide 344 perpendicular to the travelling direction of the electrical signal. Take a high-frequency electrical signal as an example, a waveguide mode field diameter 360 of the electrical signal with the signal frequency of about one THz is represented by a dashed circle. The rectangular area 344R is determined to cover a major area of the mode field diameter 360 of the electrical signal. Given the signal frequency of one THz, the waveguide width W1 of the rectangular area 344R is in a range greater than about 300 μm while the waveguide height H1 of the rectangular area 344R is in a range greater than about 80 μm. If the waveguide width W1 is less than about 300 μm or the waveguide height H1 is less than about 80 μm, the amount of the energy of the electrical signal covered by the cross section of the representative area 344R of the dielectric waveguide 344 would be too low, and therefore the energy of the electrical signal will not be confined within the rectangular area 344R of the dielectric waveguide 344, thereby causing noticeable transmission loss.

Further, the composite dielectric waveguide 344 includes one or at least three waveguide plates 344-1, 344-2, 344-3 for achieving low-loss transmission of the electrical signal since no waveguide mode can be found given only two dielectric individual dielectric waveguides 344. For example, a tri-plate dielectric waveguide 344 is formed of three dielectric waveguide plates 344-1 to 344-3, wherein a plate thickness T1 is between about 7 μm and about 10 μm, e.g., 8 μm, a plate width W1 is about 300 μm, and a plate gap G1 between adjacent plates is in a range between about 30 μm and about 40 μm. According to some embodiments, a plurality of multi-plate dielectric waveguides 344 with at least three waveguide plates provide advantages over a single-plate dielectric waveguide 344. That is because a single-plate dielectric waveguide 344 having a plate thickness H1 of approximately 80 μm will suffer from a more serious stress issue than the thinner waveguide plates with a waveguide thickness T1 of less than 10 μm.

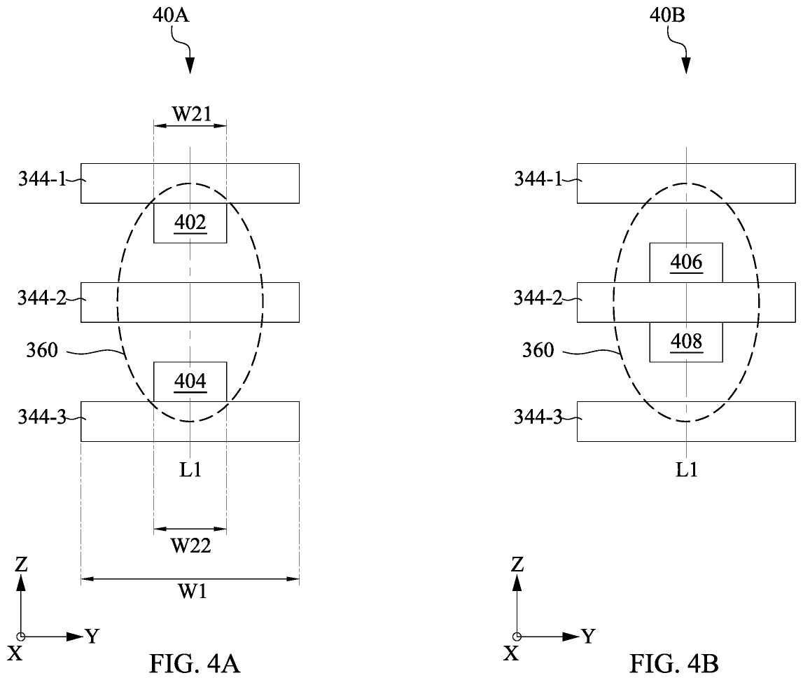

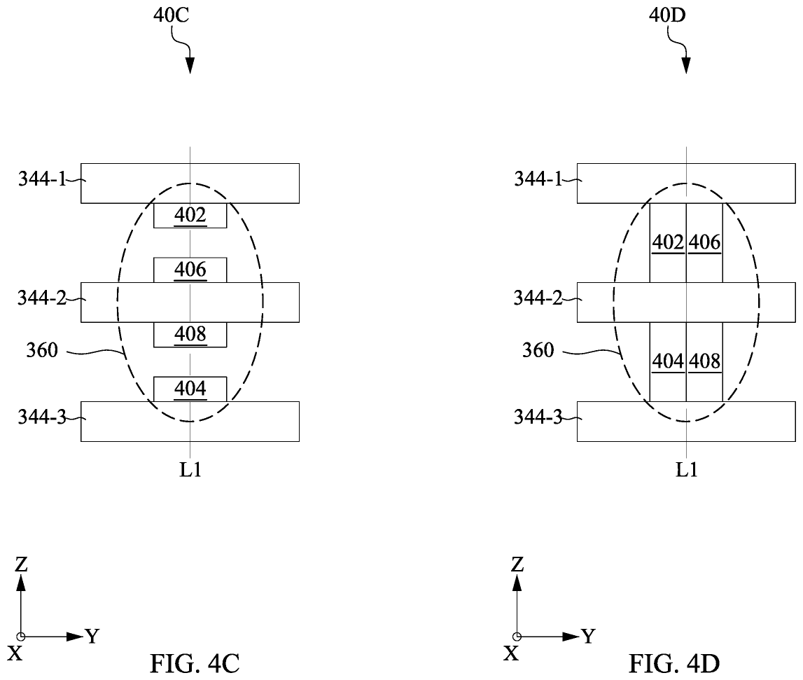

FIGS. 4A, 4B, 4C and 4D are cross-sectional views of different dielectric waveguides 40, in accordance with some embodiments of the present disclosure. The cross-sectional views of dielectric waveguides 40A, 40B, 40C and 40D are similar to the cross-sectional view shown in FIG. 3 in many aspects, and these similar features will not be repeated for the sake of brevity. The dielectric waveguides 40 include three representative waveguide plates 344-1, 344-2 and 344-3 extending in the XY-plane in a stack. The waveguide plates 344-1 to 344-3 have lateral sidewalls flushed to each other, and are wrapped around or cladded by another dielectric material (not separately shown), such as silicon oxide. Referring to FIG. 4A, the dielectric waveguide 40A further includes a protrusion 402 arranged on the waveguide plate 344-1 and a protrusion 404 arranged on the waveguide plate 344-3. The protrusions 402 and 404 may be arranged symmetric about a central line L1 of the waveguide plates 344-1 to 344-3. The protrusions 402 and 404 include widths W21 or W22, respectively, measured in the Y-axis. According to some embodiments, the widths W21 and W22 may be substantially equal or unequal. The protrusions 402 and 404 may be arranged facing the central waveguide plate 344-2. The protrusions 402 and 404 are arranged such that a majority of the areas of the protrusions 402 and 404 are within the area of the mode field diameter 360 in an attempt to confine more amount of the electrical signal than the protrusion-free dielectric waveguide 344 shown in FIG. 3. The width W21 or W22 may be in a range between about zero and about ½*W1. On one hand, if the width W21 or W22 is much less than about ½*W1, the confinement performance for the electrical signal may not be significant. On the other hand, if the width W21 or W22 is greater than about ½*W1, the effective thickness of the overall waveguide plate 344-1 and 344-3 may lead to greater stress, and the risk of breaking of the waveguide plates 344-1 and 344-3 may be increased.

Referring to FIG. 4B, the difference between the dielectric waveguide 40B and the dielectric waveguide 40A lies in that the waveguide plate 344-2 includes two protrusions 406 and 408 on a upper surface and a lower surface, respectively, of the waveguide plate 344-2. The protrusions 406 and 408 may be formed facing the waveguide plates 344-1 and 344-3, respectively. The protrusions 406 and 408 may have a width measured in the Y-axis with a range similar to that of the protrusions 402 and 404. The protrusions 406 and 408 of the waveguide plate 344-2 provide performance advantages by confining more amount of electric signals travelling through the dielectric waveguide 344, in a manner similar to the protrusions 402, 404.

Referring to FIG. 4C, the difference between the dielectric waveguide 40C and the dielectric waveguide 40A or 40B lies in that the waveguide plates 344-1, 344-2 and 344-3 include protrusions 402, 404, 406 and 408. The dielectric waveguide 40C can therefore be seen as a combination of the dielectric waveguides 40A and 40B. According to some embodiments, the protrusion 402 is facing and spaced apart from the protrusion 406, and the protrusion 404 is facing and spaced apart from the protrusion 408. The protrusions 402, 404, 406 and 408 of the waveguide plates 344-1, 344-2, 344-3 of the dielectric waveguide 40C provide greater performance enhancement by confining more amount of electric signals than the dielectric waveguide 40A or 40B at the price of a higher risk of plate breaking due to the increased stress.

Referring to FIG. 4D, the difference between the dielectric waveguide 40D and the dielectric waveguide 40C lies in that the waveguide plates 344-1, 344-2 and 344-3 are connected to each other through the protrusions 402/404 and 406/408. The dielectric waveguide 40D can therefore be seen as an expanded version of the dielectric waveguide 40A. 40B or 40C. According to some embodiments, the protrusion 402 is connected to the protrusion 406, and the protrusion 404 is connected to the protrusion 408. The protrusions 402, 404, 406 and 408 of the waveguide plates 344-1, 344-2, 344-3 of the dielectric waveguide 40D provide greater performance enhancement by confining more amount of electric signals than the dielectric waveguide 40A, 40B or 40C at the price of a higher risk of plate breaking due to the increased stress.

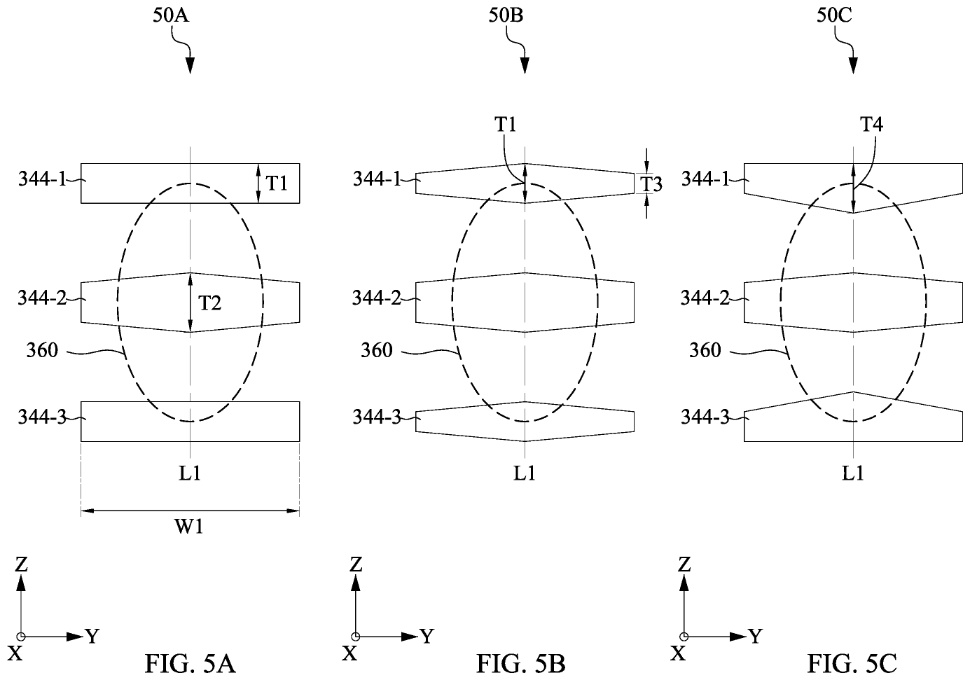

FIGS. 5A, 5B and 5C are cross-sectional views of different dielectric waveguides 50, in accordance with some embodiments of the present disclosure. The cross-sectional views of dielectric waveguides 50A, 50B and 50C are similar to the cross-sectional view shown in FIG. 3 in many aspects, and these similar features will not be repeated for the sake of brevity. The dielectric waveguides 50 includes three representative waveguide plates 344-1, 344-2 and 344-3 extending in the XY-plane in a stack. The waveguide plates 344-1 to 344-3 have lateral sidewalls flushed to each other, and are wrapped around or cladded by another dielectric material, such as silicon oxide. Referring to FIG. 5A, the waveguide plates 344-1 and 344-3 have uniform thicknesses T1 across the entire widths W1 of the waveguide plates 344-1 and 344-3. The waveguide plate 344-2 has unequal thicknesses from a central line L1 to the two sides of the waveguide plate 344-2 along the Y-axis. The waveguide plate 344-2 may have a greatest thickness T2 at the central location of the width W1, and the thickness of the waveguide plate 344-2 is monotonically decreased toward two sidewalls of the waveguide plate 344-2. The thickness T2 may be in a range between about 1.0*T1 and about 2.0*T2. The increased thickness T2 of the waveguide plate 344-2 may provide greater performance enhancement by confining more amount of electric signals than the dielectric waveguide shown in FIG. 3 at the price of a higher risk of plate breaking due to the increased stress.

Referring to FIG. 5B, the dielectric waveguide 50B has a waveguide plate 344-2 similar to that of the dielectric waveguide 50A. Further, the difference between the dielectric waveguide 50B and the dielectric waveguide 50A lies in that the dielectric waveguide plate 344-1 or 344-3 of the dielectric waveguide 50B has a non-uniform thickness across the width thereof. For example, the dielectric waveguide 344-1 or 344-3 has a tapered shape with a decreased thickness from a central location with a thickness T1 toward the two sides of the dielectric waveguide 344-1 or 344-3 with a thickness T3. The thickness T3 may be in a range of between about 0.5*T1 and about 1.0*T1. The upper surface and the lower surface of the waveguide plate 344-1 or 344-3 are tapered or slanted toward the sidewalls of the waveguide plate 344-1 or 344-3 to reach the reduced thickness T3. The reduced thickness T3 of the waveguide plate 344-1 or 344-3 may reduce the risk of plate breaking at the price of inferior performance enhancement due to less dielectric materials for confining more amount of electric signals.

Referring to FIG. 5C, the dielectric waveguide 50C has a waveguide plate 344-2 similar to that of the dielectric waveguide 50A or 50B. Further, the difference between the dielectric waveguide 50C and the dielectric waveguide 50B lies in that the dielectric waveguide plate 344-1 or 344-3 has a non-uniform thickness across the width W1 thereof. For example, the dielectric waveguide 344-1 or 344-3 has a tapered shape with a decreased thickness from an increased thickness T4 at the central location of the waveguide plate toward the two sides of the dielectric waveguide 344-1 or 344-3 with the thickness T1. The thickness T4 may be in a range of between about 1.0*T1 and about 2.0*T1. The upper surface of the waveguide plate 344-1 or and the lower surface of the waveguide plate 344-3 may be kept flat, while the lower surface of the waveguide 344-1 and the upper surface of the waveguide plate 344-3 are tapered or slanted from the central location toward the sidewalls of the waveguide plate 344-1 or 344-3 with the thickness T1. The increased thickness T4 of the waveguide plate 344-1 or 344-3 may provide greater performance enhancement by confining more amount of electric signals than the dielectric waveguide shown in FIG. 3 at the price of a higher risk of plate breaking due to the increased stress.

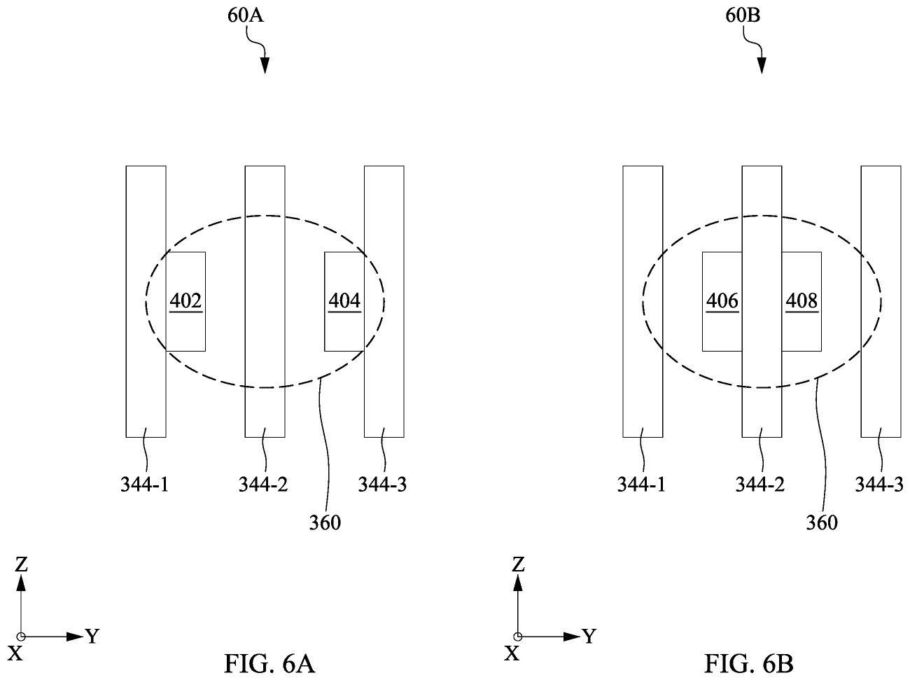

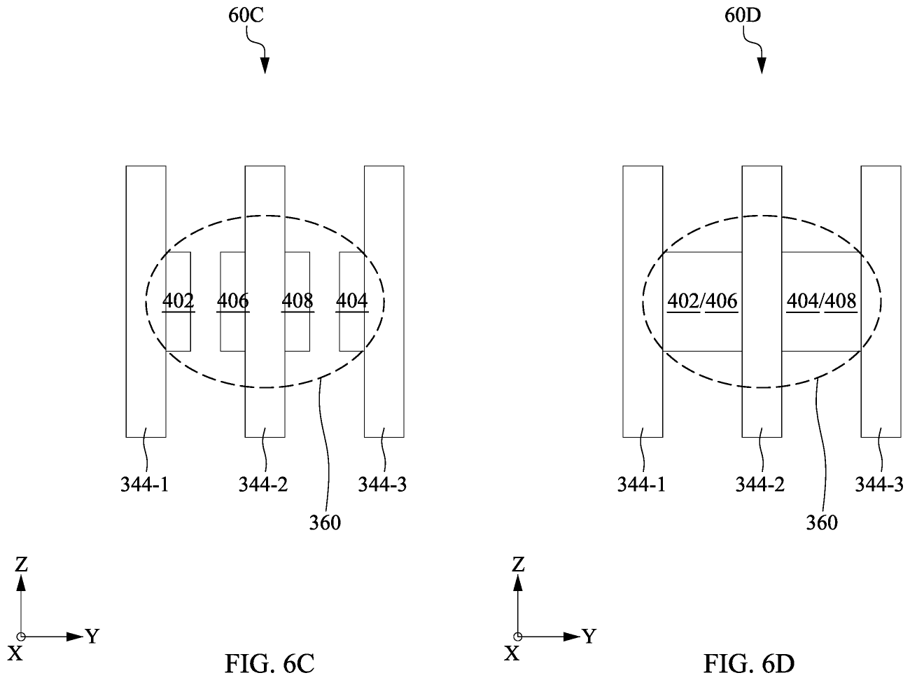

FIGS. 6A, 6B, 6C and 6D are cross-sectional views of different dielectric waveguides 60, in accordance with some embodiments of the present disclosure. The dielectric waveguides 60A, 60B, 60C and 60D correspond to their counterpart dielectric waveguides 40A, 40B, 40C and 40D, respectively, with a rotation of substantially 90 degrees in the cross-section of YZ-plane. The area of the mode field diameter 360 for the dielectric waveguides 60 is also rotated by substantially 90 degrees with respect to the mode field diameter 360 for the dielectric waveguides 40. The rotated dielectric waveguides 60 may use less circuit footprint as compared to the non-rotated dielectric waveguides 40 due to the strip shape of the cross-sectional area of the dielectric waveguides 40. The device size of the third semiconductor die 300 or 600 can be further reduced if the rotated dielectric waveguides 60 are adopted.

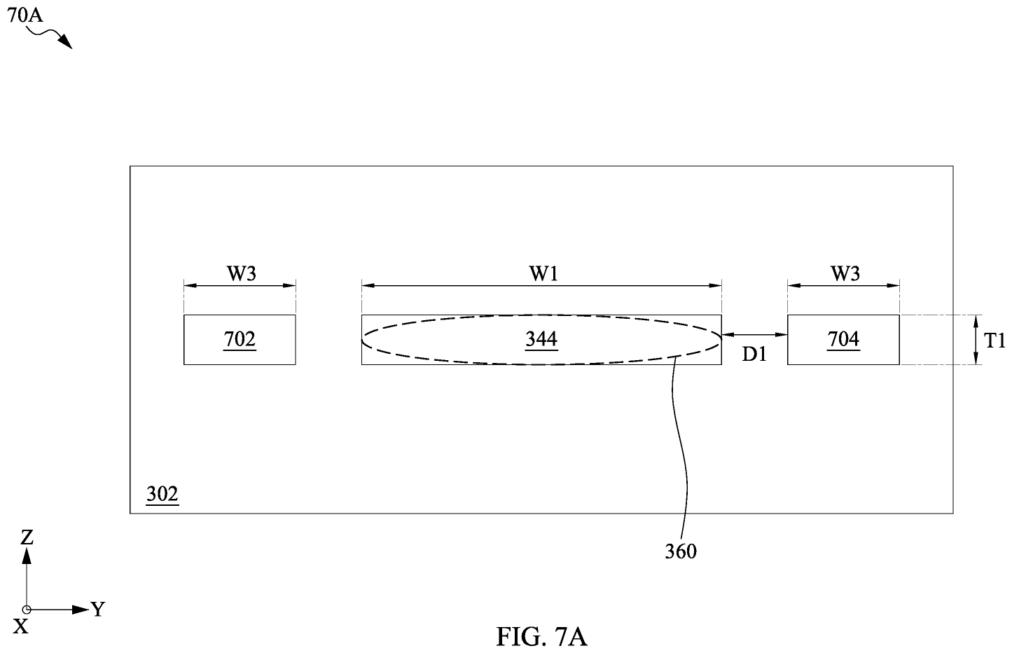

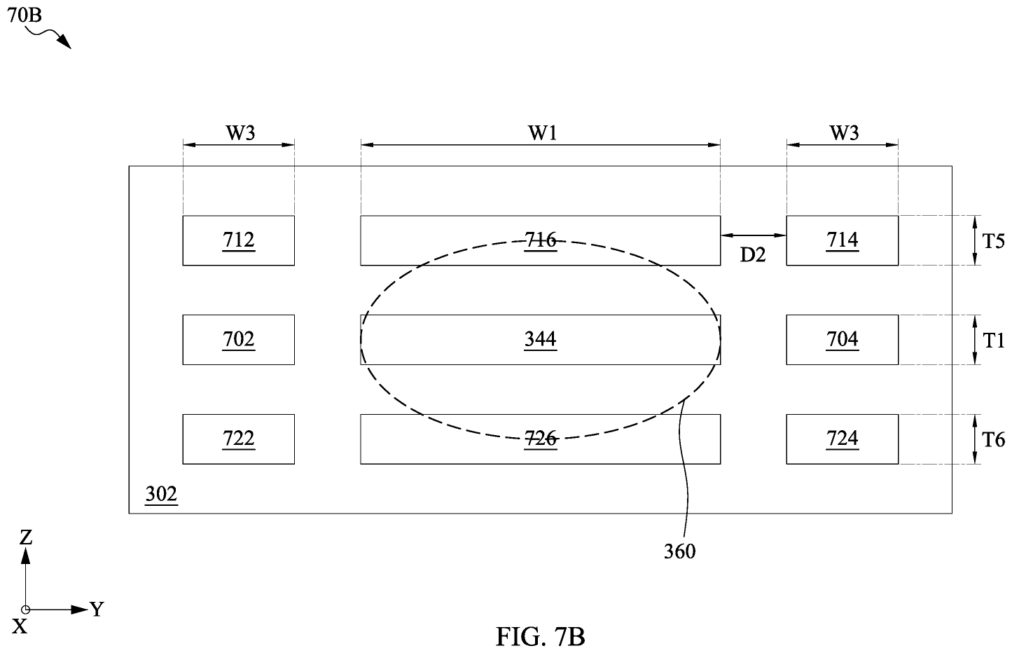

FIGS. 7A and 7B show cross-sectional views of dielectric waveguides 70, in accordance with some embodiments of the present disclosure. Referring to FIG. 3 and FIG. 7A, both of the dielectric waveguide 344 shown in FIG. 3 and FIG. 7A serve as the primary dielectric waveguide 344, in which a majority of the energy of the electrical signal, or equivalently the mode field diameter 360 of the electrical signal, is covered by the primary dielectric waveguide 344. The difference between the waveguides 344 in FIG. 3 and FIG. 7A lies in that the dielectric waveguide 70A further includes secondary dielectric waveguides 702 and 704 arranged on two sides of the primary dielectric waveguide 344. The material of the secondary dielectric waveguides 702, 704 are the same as that of the primary dielectric waveguide 344. The secondary dielectric waveguides 702, 704 may have a waveguide thickness T1 similar to that of the primary dielectric waveguide 344, and a waveguide width W3 less than the waveguide width W1 of the primary dielectric waveguide 344. The width W3 may be in range of between 0 and about ⅕*W1, and a distance D1 between the primary dielectric waveguide 344 and the secondary dielectric waveguides 702, 704 is between about 1/100*W3 and about ¼*W3, such that the secondary dielectric waveguide 702, 704 can help concentrate the energy of the electrical signal within the primary dielectric waveguide 344 and the mode field diameter 360 would be confined within the primary dielectric waveguide 344.

Referring to FIG. 7B, a dielectric waveguide 70B is shown, wherein the dielectric waveguide 70B is similar to the dielectric waveguide 70A. The main difference between the dielectric waveguide 70B and the dielectric waveguide 70A lies in that the dielectric waveguide 70B further includes secondary dielectric waveguides 712, 722, 714, 724, 716 and 726 around the primary dielectric waveguide 344. The secondary dielectric waveguides 712, 722, 714, 724, 716 and 726 may include a material similar to that of the primary dielectric waveguide 344. The dielectric waveguides 712, 716, 714, 702, 344, 704, 722, 726 and 724 may form a rectangular array of dielectric waveguides, in which the majority of the mode field diameter 360 is concentrated around the primary dielectric waveguide 344. The dimensions T5, T6, D2, and G2 of the dielectric waveguide 70B are determined to ensure that the secondary dielectric waveguides 702, 704, 712, 714, 716, 722, 724 and 726 can help concentrate the energy of the electrical signal within the primary dielectric waveguide 344 and the mode field diameter 360 would be confined within the primary dielectric waveguide 344. According to some embodiments, the secondary dielectric waveguides 712, 716, 714 have a waveguide thickness T5 substantially equal to or unequal to the waveguide thickness T1, the secondary dielectric waveguides 722, 726, 724 have a waveguide thickness T6 substantially equal to or unequal to the waveguide thickness T1, and the secondary dielectric waveguides 702, 704 may have a waveguide thickness T1 substantially equal to that of the primary dielectric waveguide 344. According to some embodiments, a distance D2 between horizontally adjacent secondary dielectric waveguides, e.g., between secondary dielectric waveguides 726 and 724, may be in a range between about 1/100*W3 and about ¼*W3. A gap G2 between vertically adjacent secondary dielectric waveguides, e.g., between secondary dielectric waveguides 704 and 714, may be in a range between about 0.01*T1 and about 0.05*T1.

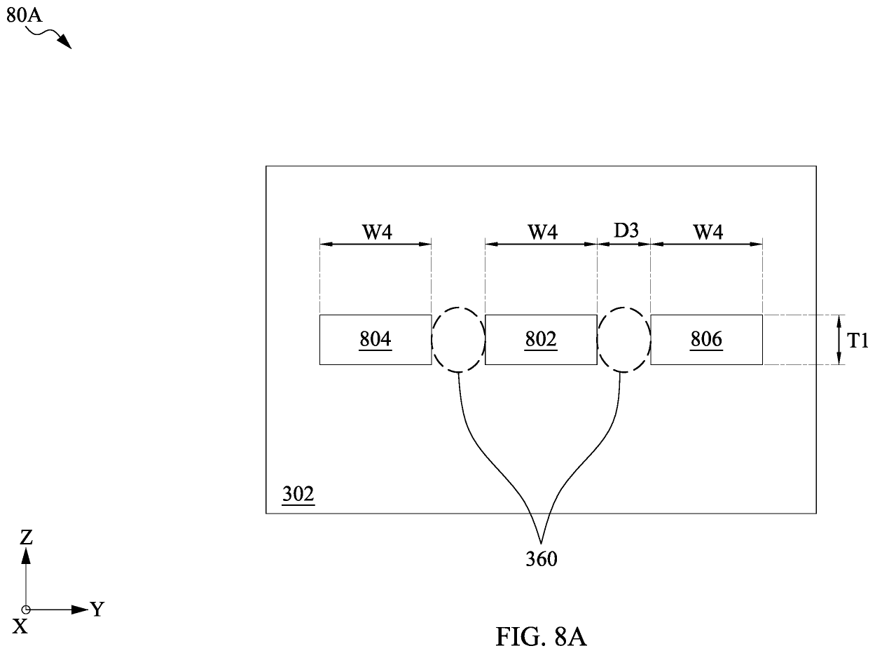

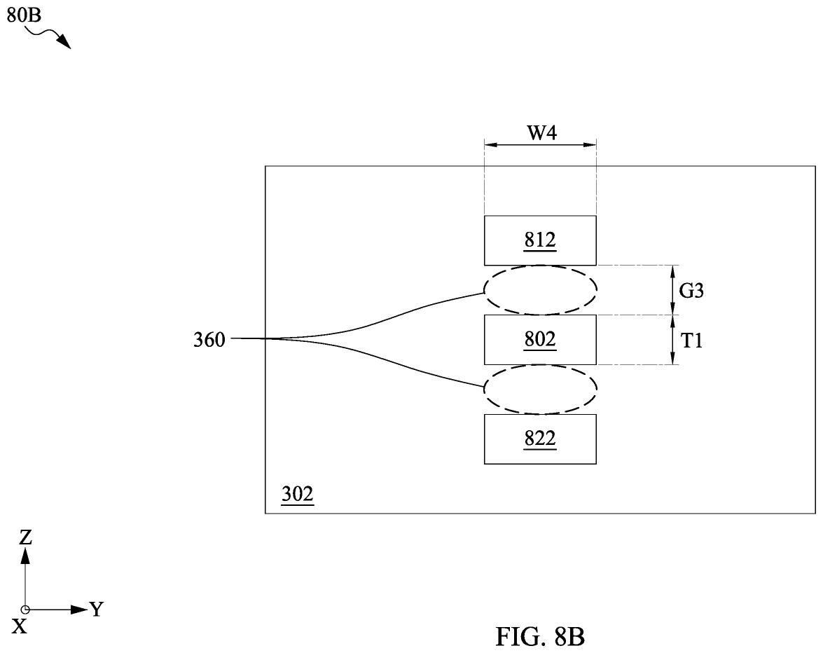

FIGS. 8A and 8B show cross-sectional views of dielectric waveguides 80, in accordance with some embodiments of the present disclosure. The working principle of the dielectric waveguides 80 is different from that with reference to the previous figures in that the dielectric waveguides 80 do not have a primary dielectric waveguide to confine the mode field diameter 360 of the electric signal. Referring to FIG. 8A, the dielectric waveguide 80A includes a number (equal to or greater than three) of horizontally arranged waveguide plates 802, 804, 806 arranged parallel to each other in the Y-axis. The waveguide plates 802, 804, 806 have substantially equal widths W4 less than the minimal width W1 qualified as the primary dielectric waveguide 433, and as a result the majority of the energy of the electrical signal or the mode field diameter 360 is formed in spaces between the adjacent dielectric waveguide plates 802, 804, 806. The dimensions of the dielectric waveguide 80A are determined such that the mode field diameter 360 is formed in the spaces between the waveguide plates 802, 804, 806 rather than within any of the waveguide plates 802, 804, 806. According to some embodiments, the width W4 of the waveguide plates 802, 804, 806 is in a range between about ⅙*W1 and about ⅓*W1. According to some embodiments, the spacing D3 of the spaces between the horizontally adjacent waveguide plates 802, 804, 806 is in a range between about 0.1*W4 and about 0.5*W4.

Referring to FIG. 8B, a dielectric waveguide 80B is shown, wherein the dielectric waveguide 80B is similar to the dielectric waveguide 80A. The main difference between the dielectric waveguide 80B and the dielectric waveguide 80A lies in that the dielectric waveguide 80B includes vertically arranged dielectric waveguides 812, 814, 816. The waveguide plates 812, 814, 816 have a width W4 less than the minimal width W1 qualified as the primary dielectric waveguide 433, and as a result the majority of the energy of the electrical signal is formed in gaps between the vertically adjacent waveguide plates 812, 814, 816. The dimensions of the dielectric waveguide 80B are determined such that the mode field diameter 360 is formed in the gaps between the waveguide plates 812, 814, 816 rather than within any of the waveguide plates 812, 814, 816. According to some embodiments, the width W4 of the waveguide plates 812, 814, 816 is in a range between about ⅙*W1 and about ⅓*W1. According to some embodiments, the length of the gaps G3 between the waveguide plates 812, 814, 816 is in a range between about 0.01*T1 and about 0.05*T1.

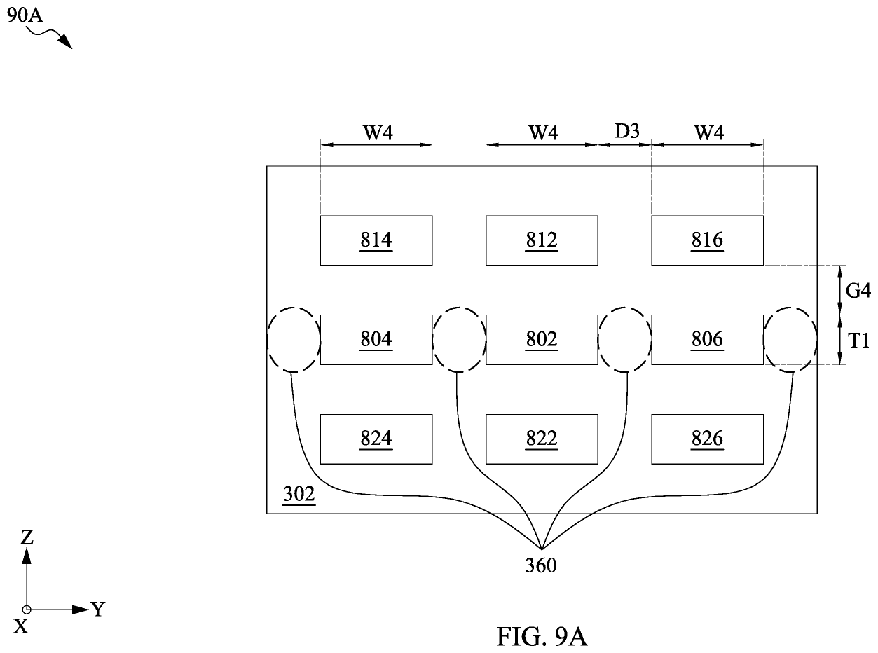

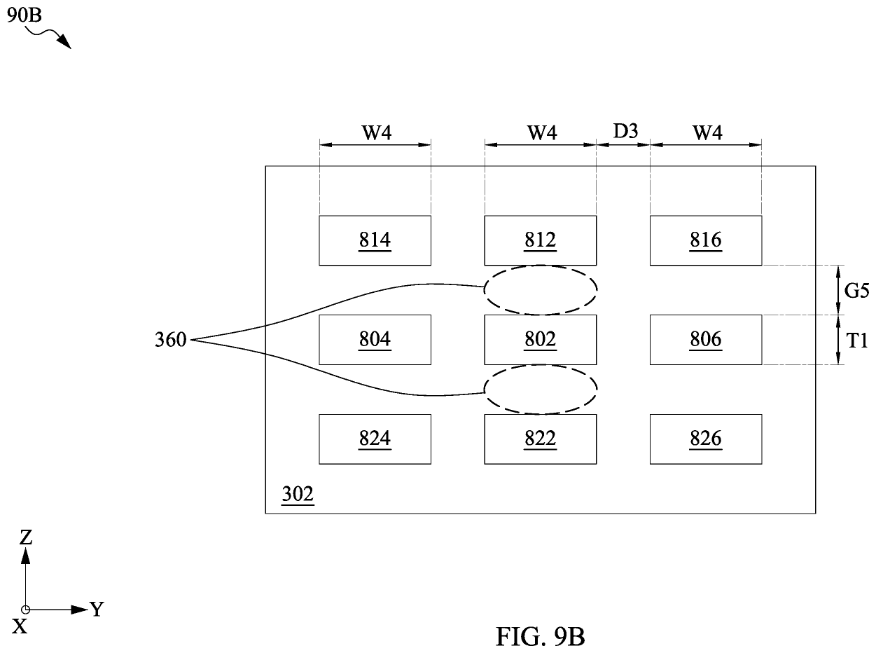

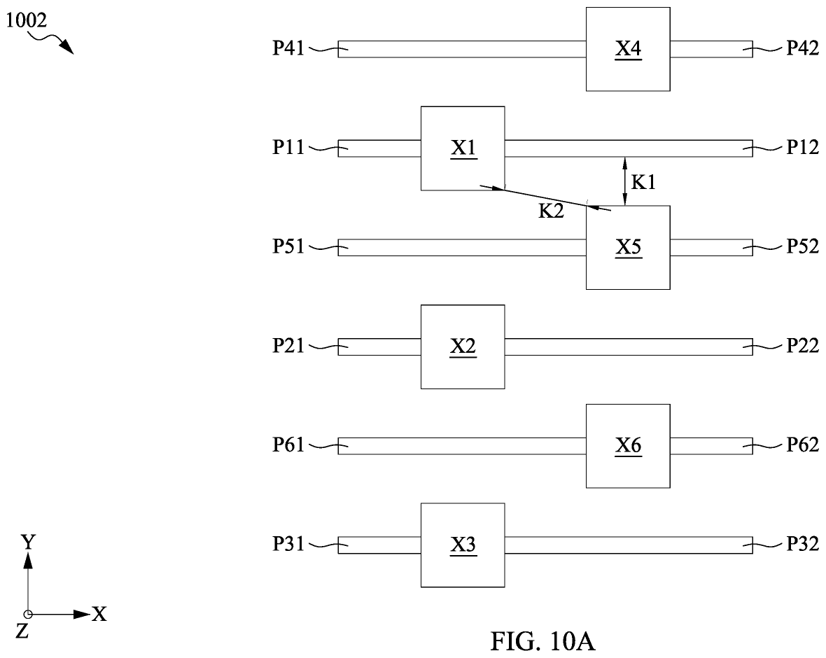

FIGS. 9A and 9B show cross-sectional views of dielectric waveguides 90, in accordance with some embodiments of the present disclosure. Referring to FIG. 9A, a dielectric waveguide 90A is shown, which is similar to the dielectric waveguide 80A or 80B. The main difference between the dielectric waveguide 90A and the dielectric waveguide 80A lies in that the dielectric waveguide 90A further includes a plurality of waveguide plates 812, 814, 816, 822, 824, 826 in an overlying layer and an underlying layer of the waveguide plates 802, 804, 806. The waveguide plates 802, 804, 806, 812, 814, 816, 822, 824, 826 may form an array of waveguide plates for the dielectric waveguide 90A, and dimensions of the dielectric waveguide 90A are determined to ensure that the mode field diameter 360 is formed in the spaces between the waveguide plates 802, 804, 806, 812, 814, 816, 822, 824, 826 rather than within any of the waveguide plates 802, 804, 806, 812, 814, 816, 822, 824, 826. According to some embodiments, the spacing D3 of the spaces between the horizontally adjacent waveguide plates 802, 804. 806 is in a range between about 0.1*W4 and about 0.5*W4. According to some embodiments, the length of the gaps G4 between the vertically adjacent waveguide plates 802, 804, 806, 812, 814, 816, 822, 824, 826 is substantially equal to the spacing D3.

Referring to FIG. 9B, a dielectric waveguide 90B is shown, which is similar to the dielectric waveguide 90A. The main difference between the dielectric waveguide 90B and the dielectric waveguide 90A may lie in the gaps G5 between vertically adjacent waveguide plates 802, 804, 806, 812, 814, 816, 822, 824, 826 are different to the gaps G4 shown in FIG. 9A. The dimensions for the spaces D3 and gaps G5 of the dielectric waveguide 90A are determined to ensure that the mode field diameter 360 is formed in the gaps G5 between the waveguide plates 802, 804, 806, 812, 814, 816, 822, 824, 826 rather than within any of the waveguide plates 802, 804, 806, 812, 814, 816, 822, 824, 826. According to some embodiments, the length of the gaps G5 between the vertically adjacent waveguide plate is in a range between about 0.01*T1 and about G4.

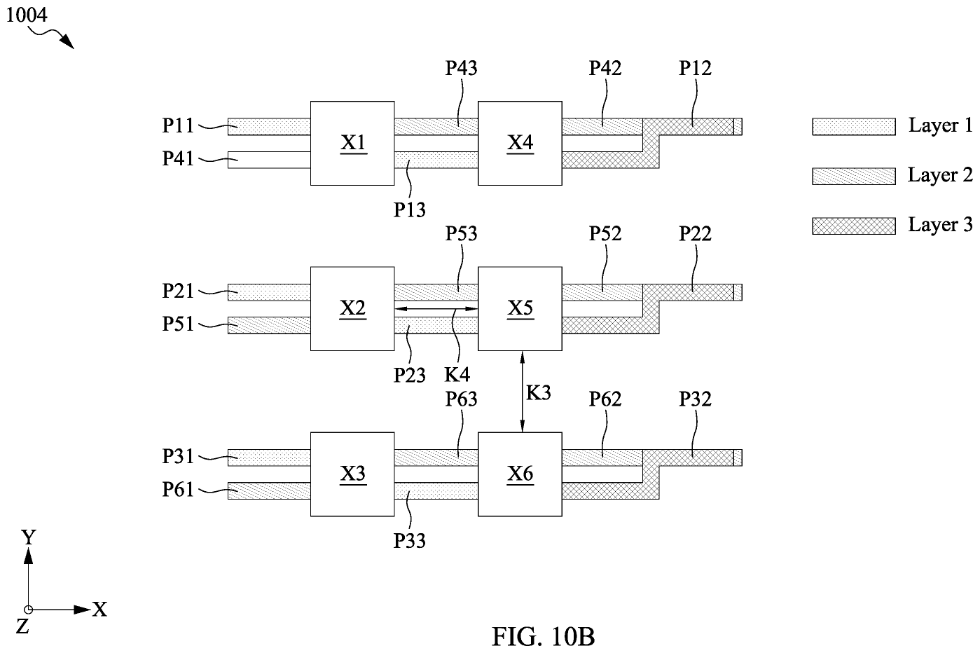

FIG. 10A shows a block diagram of a single-layer interconnect structure 1002, in accordance with some comparative embodiments of the present disclosure. The interconnect structure 1002 includes exemplary optical devices X1, X2, X3, X4, X5 and X6 arranged in a same layer, e.g., Layer 1. Each of the optical devices X1 through X6 includes a respective input waveguide P11, P21, P31, P41, P51 and P61, and a respective output waveguide P12, P22, P32, P42, P52 and P62. In order to ensure sufficient optical insulation between any two of the optical features, e.g., devices X1 through X6, the input waveguides P11 through P61 and the output waveguides P12 and P62, one or more distances between these optical features are determined. According to some embodiments, a minimal distance K1 is defined as a distance between an optical device and an adjacent waveguide, e.g., between the optical device X5 and its adjacent output waveguide P12. The minimal distance K1 may be in an order of tens of μm. According to some embodiments, a minimal distance K2 is defined as a distance between two adjacent optical devices, e.g., between the optical devices X1 and X5. The minimal distance K1 may be in an order of tens of μm. Since all of the optical features mentioned above are arranged in the same Layer 1, the minimal distance K1 or K2 should be a relatively large number.

FIG. 10B shows a block diagram of a multilayer interconnect structure 1004, in accordance with some embodiments of the present disclosure. The interconnect structure 1004 includes the exemplary optical devices X1, X2, X3, X4, X5 and X6 arranged in a same layer, e.g., Layer 1. Each of the optical devices X1 through X6 includes respective input waveguide P11, P21, P31, P41, P51 and P61, respective output waveguide P12, P22, P32, P42, P52 and P62, and respective middle waveguides P13, P23, P33. P43, P53 and P63. Different from the layout of the interconnect structure 1002, in the interconnect structure 1004 the aforementioned input waveguides P11 through P16, the output waveguides P12 through P62 and the middle waveguides P13 through P63 can be arranged in different layers, e.g., Layer 1. Layer 2 or Layer 3. Referring to FIG. 2A and FIG. 10B, the three layers of the interconnect structure 1004 may correspond to three layers where the dielectric waveguides 640A, 640B, 640C, 640D and 640E reside. According to some embodiments, the spacing between adjacent layers of the third semiconductor die 600 may be in a range of tens of μm. As a result, the optical devices X1 through X6 can be arranged more closely to each other from a top-view perspective as long as minimal distances K3 and K4 between adjacent optical devices is determined to be at least the greater of the minimal distances K1 and K2. The interconnect structure 1004 provides a layout advantage over the interconnect structure 1002 in that the input waveguides P11 through P16 can be arranged in different layers with a sufficiently large insulation distance but are overlapped from a top-view perspective. The same layout advantage can also be applicable to the output waveguides P12 through P62. As a result, the horizontal distances between the input waveguides P11 through P16 or between the output waveguides are reduced, and the device area can be further lowered. Based on the above, the multi-plate dielectric waveguide 344 shown in FIGS. 3, 4A to 4D, 5A to 5C, 7B. 8B. 9A and 9B can be arranged together with the interconnect structure 1004 to provide electrical waveguides and optical waveguides in a same interconnect structure with a compact device footprint.

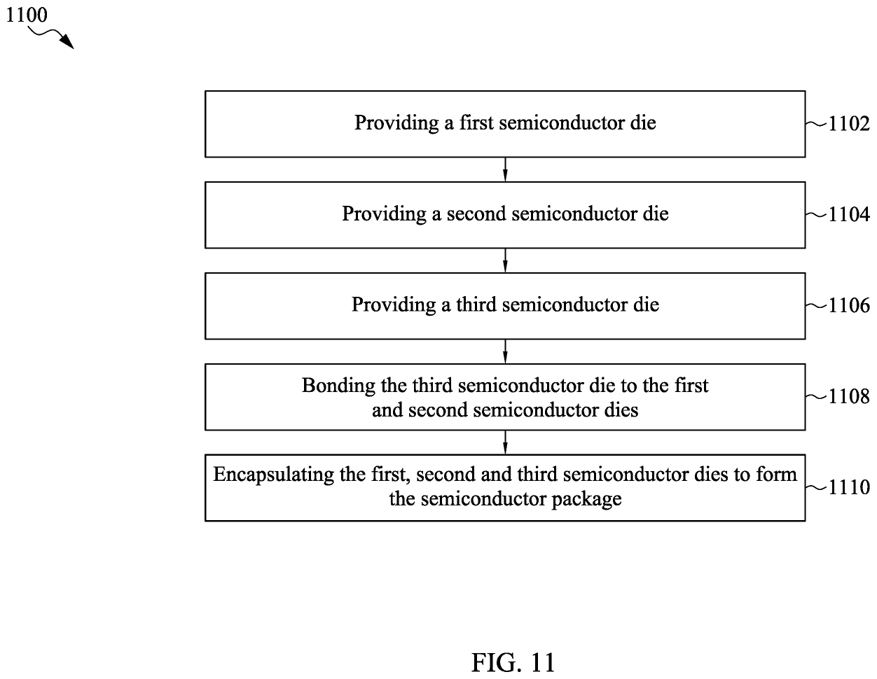

FIG. 11 is a flowchart of a method 1100 of forming a semiconductor package, in accordance with some embodiments of the present disclosure. It should be understood that additional steps can be provided before, during, and after the steps shown in FIG. 11, and some of the steps described below can be replaced or eliminated, for additional embodiments of the method 1100. The order of the steps may be changed. Materials, configurations, dimensions, processes and/or operations the same as or similar to those described with respect to the foregoing embodiments may be employed in the following embodiments, and the detailed explanation thereof may be omitted.

At step 1102, a first semiconductor die, e.g., the first semiconductor die 100 or 400, is provided or formed. At step 1104, a second semiconductor die, e.g., the second semiconductor die 200 or 500, is provided or formed.

At step 1106, a third semiconductor die, e.g., the third semiconductor die 300 or 600, is provided or formed. At step 1108, the third semiconductor die is bonded to the first semiconductor die and the second semiconductor die.

At step 1110, the first semiconductor die, the second semiconductor die and the third semiconductor die are encapsulated by a molding material, e.g., a dielectric material or a polymeric material.

In accordance with some embodiments of the present disclosure, a semiconductor structure includes: a first electrical waveguide formed of a first dielectric material and configured to transmit an electrical signal; a second electrical waveguide formed of the first dielectric material and disposed adjacent to a first side of the first electrical waveguide; and a third electrical waveguide formed of the first dielectric material and disposed adjacent to a second side of the first electrical waveguide opposite the first side. The second electrical waveguide and the third electrical waveguide are configured to form a composite waveguide together with the first electrical waveguide for transmission of the electrical signal.

In accordance with some embodiments of the present disclosure, a semiconductor package includes: a first semiconductor die including a first semiconductor device configured to transmit an electrical signal; a second semiconductor die adjacent to the first semiconductor die and including a second semiconductor device configured to receive the electrical signal; and a third semiconductor die adjacent to the first semiconductor die and the second semiconductor die. The third semiconductor die includes: a first signal path including a plurality of first waveguides formed of a first dielectric material, the first signal path configured to transmit the electrical signal between the first semiconductor die and the second semiconductor die; and a second signal path adjacent to the first signal path and including a plurality of second waveguides formed of a second dielectric material, the second signal path configured to transmit an optical signal and convert the optical signal to be part of the electrical signal.

In accordance with some embodiments of the present disclosure, a method of forming a semiconductor package includes: providing a first semiconductor die, wherein the first semiconductor die includes a first electronic device configured to transmit an electrical signal; providing a second semiconductor die, wherein the second semiconductor die includes a second electronic device configured to receive the electronic signal; and providing a third semiconductor die. The third semiconductor die includes: a first signal path including a plurality of first waveguides formed of a first dielectric material, the first signal path configured to transmit the electrical signal; and a second signal path adjacent to the first signal path and including a plurality of second waveguides formed of a second dielectric material, the second signal path configured to transmit an optical signal. The method further includes bonding the third semiconductor die to the first semiconductor die and the second semiconductor die, wherein the first semiconductor die is electrically coupled to the second semiconductor die through the first signal path and the second signal path.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first electrical waveguide formed of a first dielectric material and configured to transmit an electrical signal;
a second electrical waveguide formed of the first dielectric material and disposed adjacent to a first side of the first electrical waveguide; and
a third electrical waveguide formed of the first dielectric material and disposed adjacent to a second side of the first electrical waveguide opposite the first side,
wherein the second electrical waveguide and the third electrical waveguide are configured to form a composite waveguide together with the first electrical waveguide for transmission of the electrical signal.

2. The semiconductor structure of claim 1, wherein the first dielectric material comprises silicon nitride.

3. The semiconductor structure of claim 1, wherein the electrical signal has a frequency between about 70 gigahertz and about 100 terahertz.

4. The semiconductor structure of claim 1, wherein a thickness of each the first electrical waveguide, the second electrical waveguide and the third electrical waveguide is between about 7 μm and about 10 μm.

5. The semiconductor structure of claim 1, wherein a first width of the first electrical waveguide is greater than a second width of the second electrical waveguide or the third electrical waveguide, and wherein a mode field diameter of the electrical signal is substantially covered by the first electrical waveguide.

6. The semiconductor structure of claim 1, wherein one of the second electrical waveguide and the third electrical waveguide comprises a protrusion extending from the respective second or third electrical waveguide and facing the first electrical waveguide.

7. The semiconductor structure of claim 6, wherein the protrusion is connected to the first electrical waveguide.

8. The semiconductor structure of claim 1, wherein a thickness of at least one of the first electrical waveguide, the second electrical waveguide and the third electrical waveguide increases from two sides to a central location of the at least one of the first electrical waveguide, the second electrical waveguide and the third electrical waveguide.

9. The semiconductor structure of claim 1, further comprising:
a fourth electrical waveguide formed of silicon nitride and disposed adjacent to a third side of the first electrical waveguide; and
a fifth electrical waveguide formed of silicon nitride and disposed adjacent to a fourth side of the first electrical waveguide opposite the third side,
wherein the fourth electrical waveguide and the fifth electrical waveguide are configured to form a composite electrical waveguide together with the first, second and third electrical waveguides for the electrical signal.

10. The semiconductor structure of claim 1, wherein a mode field diameter of the electrical signal is formed in gaps between the first, second and third electrical waveguides.

11. The semiconductor structure of claim 10, wherein a first width of the first electrical waveguide is substantially equal to a second with of the second and third electrical waveguides.

12. The semiconductor structure of claim 11, further comprising a plurality of fourth electrical waveguides to form an array of electrical waveguides together with the first, second, and third electrical waveguides, wherein a mode field diameter is covered substantially by the first electrical waveguide.

13. A semiconductor package, comprising:
a first semiconductor die comprising a first semiconductor device configured to transmit an electrical signal;
a second semiconductor die adjacent to the first semiconductor die and comprising a second semiconductor device configured to receive the electrical signal; and
a third semiconductor die adjacent to the first semiconductor die and the second semiconductor die, the third semiconductor die comprising:
a first signal path comprising a plurality of first waveguides formed of a first dielectric material, the first signal path configured to transmit the electrical signal between the first semiconductor die and the second semiconductor die; and
a second signal path adjacent to the first signal path and comprising a plurality of second waveguides formed of a second dielectric material, the second signal path configured to transmit an optical signal and convert the optical signal to be part of the electrical signal.

14. The semiconductor package of claim 13, wherein the first dielectric material comprises silicon nitride, and the second dielectric material comprises elementary silicon.

15. The semiconductor package of claim 13, wherein the third semiconductor die further comprises:
a vertical transition device electrically coupled to the first signal path and configured to transmit the electrical signal to the first semiconductor die through the first signal path; and
an optical device optically coupled to the second signal path and configured to transmit the optical signal to the second semiconductor die through the second signal path.

16. The semiconductor package of claim 13, wherein one of the first waveguides overlap the first semiconductor die and the second semiconductor die from a top-view perspective.

17. The semiconductor package of claim 13, wherein the first waveguides are arranged in different layers of the third semiconductor die for transmitting the electrical signal, wherein the second waveguides are also arranged in the different layers for transmitting the optical signal.

18. A method of forming a semiconductor package, comprising:
providing a first semiconductor die, wherein the first semiconductor die comprises a first electronic device configured to transmit an electrical signal;
providing a second semiconductor die, wherein the second semiconductor die comprises a second electronic device configured to receive the electrical signal;
providing a third semiconductor die, wherein the third semiconductor die comprises:
a first signal path comprising a plurality of first waveguides formed of a first dielectric material, the first signal path configured to transmit the electrical signal; and
a second signal path adjacent to the first signal path and comprising a plurality of second waveguides formed of a second dielectric material, the second signal path configured to transmit an optical signal; and
bonding the third semiconductor die to the first semiconductor die and the second semiconductor die, wherein the first semiconductor die is electrically coupled to the second semiconductor die through the first signal path and the second signal path.

19. The method of claim 18, wherein the providing of the third semiconductor die further comprises encapsulating the first waveguides and the second waveguides by a third dielectric material different from the first and second dielectric materials.

20. The method of claim 18, wherein the providing of the third semiconductor die further comprises providing a photodetectors configured to convert the optical signal to be part of the electrical signal.
